(19) United States
(12) Patent Application Publication
(10) Pub. No.: US 2012/0032154 A1
(43) Pub. Date: Feb. 9, 2012

(54) SEMICONDUCTOR DEVICE, DISPLAY DEVICE AND ELECTRONIC EQUIPMENT

(75) Inventor: Mao Katsuhara, Kanagawa (JP)

(73) Assignee: SONY CORPORATION, Tokyo (JP)

(21) Appl. No.: 13/192,830

(22) Filed: Jul. 28, 2011

(30) Foreign Application Priority Data
Aug. 6, 2010 (JP) 2010-177798

(51) Int. Cl. H01L 51/30; H01L 29/786

(52) U.S. Cl. 257/40; 257/57; 257/59; 257/E51.006; 257/E29.273

(57) ABSTRACT

Disclosed herein is a semiconductor device including: a gate electrode; a gate insulating film; an organic semiconductor layer; and source and drain electrodes.

### BACKGROUND

The present disclosure relates to a semiconductor device, display device and electronic equipment, and more particularly to a semiconductor device that includes a thin film transistor having an organic semiconductor layer, and to a display device and electronic equipment having the same.

Semiconductor devices using an organic semiconductor layer as an active layer having a channel region formed therein, i.e., so-called organic thin film transistors (organic TFTs), are classified into four types according to the positional relationship between the gate electrode and the source and drain electrodes with respect to the organic semiconductor layer. For example, the bottom gate structure having the gate electrode below the organic semiconductor layer is divided into two different types, namely, the top contact structure and bottom contact structure. In the top contact structure, the source and drain electrodes are located on top of the organic semiconductor layer. In the bottom contact structure, the source and drain electrodes are located under the organic semiconductor layer (refer to “Advanced Materials,” (2002), vol. 14, p. 99).

Of these structures, the top contact structure offers more solid contact between the source and drain electrodes and the organic semiconductor layer, thus ensuring extremely high reliability.

### SUMMARY

Incidentally, in semiconductor devices using an organic semiconductor layer in general, it is known that the channel region taking charge of the conduction of electric charge in the organic semiconductor layer serving as an active layer is an extremely limited region, spanning about several molecular layers (up to 10 nm) from the interface of the gate insulating film.

In a semiconductor device having the above bottom gate and top contact structure, however, the source and drain electrodes are in contact with the inactive region of the organic semiconductor layer that does not serve as a channel region. As a result, the inactive region of the organic semiconductor layer having a large resistance is provided between the source and drain electrodes and the channel region, making it difficult to reduce the contact resistance (injection resistance) of the source and drain electrodes to the channel region.

Although the resistance of the inactive region can be reduced by thinning the organic semiconductor layer, it is difficult to uniformly form an extremely thin film of up to 10 nm in thickness in the large area process. On the other hand, it is difficult to achieve excellent characteristics of the organic semiconductor layer in the region of such a thin film. Moreover, the channel region of the organic semiconductor layer is prone to damage in the process following the film formation.

In light of the foregoing, it is desirable to provide a semiconductor device having a top contact structure with solid contact between the source and drain electrodes and the organic semiconductor layer that offers reduced contact resistance while at the same time securing an appropriate film quality of the organic semiconductor layer, thus contributing to improved reliability and functionality. It is also desirable to provide a display device and electronic equipment with improved functionality thank to the semiconductor device incorporated therein.

According to the present disclosure, there is provided a semiconductor device that includes a gate electrode on a substrate, gate insulating film, organic semiconductor layer and source and drain electrodes. The gate insulating film covers the gate electrode. The organic semiconductor layer is provided on top of the gate insulating film. The source and drain electrodes are provided on top of the organic semiconductor layer. The organic semiconductor layer is stacked above the gate electrode with the gate insulating film therebetween in such a manner as to cover the gate electrode along the width of the gate electrode. The organic semiconductor layer has a thick film portion and thin film portions. The thick film portion is arranged at the center along the width of the gate electrode. The thin film portions are thinner than the thick film portion and arranged each at one end along the width of the gate electrode. The source and drain electrodes are arranged to be opposed to each other with the gate electrode sandwiched therebetween along the width of the gate electrode, with the end portion of each of the source and drain electrodes stacked on one of the thin film portions. Further, it is particularly preferred that the thick film portion of the organic semiconductor layer should fit within the width of the gate electrode and that the thin film portions should extend outward from the thick film portion along the width of the gate electrode.

The present disclosure is also a display device and electronic equipment having the semiconductor device according to the present disclosure.

The semiconductor device configured as described above is an organic thin film transistor having a bottom gate and top contact structure. Therefore, source and drain electrodes are stacked each on top of one of the ends of the organic semiconductor layer along the width of the gate electrode. This provides a solid contact with the organic semiconductor layer. On the other hand, both ends of the organic semiconductor layer along the width of the gate electrode, in particular, are formed as the thin film portions, with the end portion of each of the source and drain electrodes stacked thereon. This maintains constant the thickness of the central portion of the organic semiconductor layer stacked above the gate electrode, i.e., the thickness of the upper portion of the channel region, while at the same time thinning the organic semiconductor layer at both ends of the channel region, thus providing reduced resistance between the channel region and the source and drain electrodes.

As described above, the present disclosure provides reduced resistance between the channel region and the source and drain electrodes irrespective of the thickness of the area of the organic semiconductor layer for the channel region despite the fact that the semiconductor device has a bottom gate and top contact structure. This makes it possible to reduce the contact resistance (injection resistance) of the source and drain electrodes to the channel region while at the same time securing an appropriate film quality of the area of the organic semiconductor layer for the channel region, thus contributing to improved reliability and functionality of the semiconductor device. This also contributes to improved reliability and functionality of the display device and electronic equipment having the semiconductor device configured as described above.

### BRIEF DESCRIPTION OF THE DRAWINGS

FIGS. 1A and 1B are cross-sectional and plan views illustrating the configuration of a semiconductor device according to a first embodiment;

FIGS. 2A to 2E are cross-sectional process diagrams illustrating a manufacturing method (1) of the semiconductor device according to the first embodiment;

FIGS. 3A to 3E are cross-sectional process diagrams illustrating a manufacturing method (2) of the semiconductor device according to the first embodiment;

FIGS. 4A to 4E are cross-sectional process diagrams illustrating a manufacturing method (3) of the semiconductor device according to the first embodiment;

FIGS. 5A and 5B are cross-sectional and plan views illustrating the configuration of a semiconductor device according to a second embodiment;

FIGS. 6A to 6E are cross-sectional process diagrams illustrating an example of the manufacturing method of the semiconductor device according to the second embodiment;

FIGS. 7A and 7B are cross-sectional and plan views illustrating the configuration of a semiconductor device according to a third embodiment;

FIGS. 8A to 8E are cross-sectional process diagrams illustrating an example of the manufacturing method of the semiconductor device according to the third embodiment;

FIGS. 9A and 9B are cross-sectional and plan views illustrating the configuration of a semiconductor device according to a fourth embodiment;

FIGS. 10A to 10C are process diagrams (1) illustrating the features of the manufacturing method of the semiconductor device according to the fourth embodiment;

FIGS. 10D and 10E are process diagrams (2) illustrating the features of the manufacturing method of the semiconductor device according to the fourth embodiment;

FIG. 11 is a cross-sectional view illustrating an example of a display device according to a fifth embodiment;

FIG. 12 is a circuit configuration diagram of the display device according to the fifth embodiment;

FIG. 13 is a perspective view illustrating a television set using the display device according to the present disclosure;

FIGS. 14A and 14B are perspective views illustrating a digital camera using the display device according to the present disclosure, and FIG. 14A is a perspective view as seen from the front, and FIG. 14B is a perspective view as seen from the rear;

FIG. 15 is a perspective view illustrating a laptop personal computer using the display device according to the present disclosure;

FIG. 16 is a perspective view illustrating a video camcorder using the display device according to the present disclosure; and

FIGS. 17A to 17G are perspective views illustrating a personal digital assistance such as mobile phone using the display device according to the present disclosure, and FIG. 17A is a front view in an open position, FIG. 17B is a side view thereof, FIG. 17C is a front view in a closed position, FIG. 17D is a left-side view, FIG. 17E is a right-side view, FIG. 17F is a top view, and FIG. 17G is a bottom view.

### DETAILED DESCRIPTION OF THE PREFERRED EMBODIMENTS

A description will be given below of the preferred embodiments of the present disclosure with reference to the accompanying drawings in the following order.

1. First embodiment (example of embodiment of a semiconductor device)

2. Second embodiment (example of embodiment of a semiconductor device having a protective film)

3. Third embodiment (example of embodiment of a semiconductor device having an organic semiconductor layer made up of two layers)

4. Fourth embodiment (example of embodiment of a semiconductor device in which the end portions of the source and drain electrodes are aligned with those of the gate electrode)

5. Fifth embodiment (example of application to a display device using thin film transistors)

6. Sixth embodiment (example of application to electronic equipment)

It should be noted that the same components in the first to fourth embodiments are denoted by the same reference symbols, and the description thereof is omitted to avoid redundancy.

### 1. FIRST EMBODIMENT

### <Configuration of the Semiconductor Device>

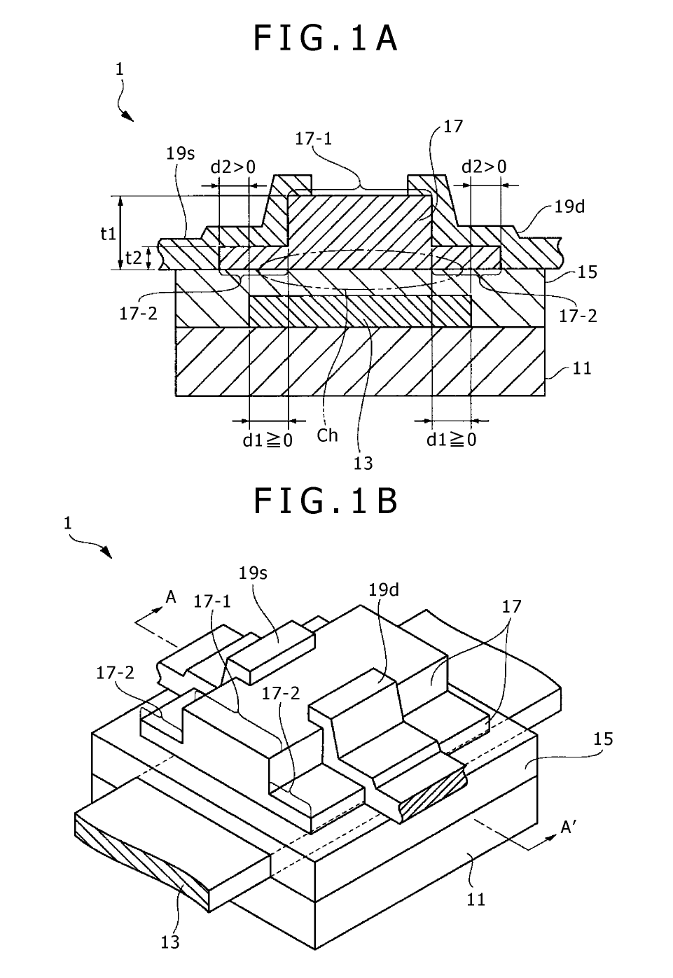

FIGS. 1A and 1B are cross-sectional and plan views illustrating the configuration of a semiconductor device 1 according to a first embodiment. The cross-sectional view illustrates the cross-section taken along line A-A′ in the plan view. The semiconductor device 1 shown in these views is a thin film transistor having a bottom gate and top contact structure. A gate insulating film 15 is provided on top of a substrate 11 in such a manner as to cover a gate electrode 13 that extends in one direction. An organic semiconductor layer 17 is provided on top of the gate insulating film 15. The organic semiconductor layer 17 is patterned in the form of an island above the gate electrode 13 and stacked above the same electrode 13 with the gate insulating film 15 therebetween. Further, source and drain electrodes 19s and 19d are provided to be opposed to each other on the gate insulating film 15 with the gate electrode 13 sandwiched therebetween. The edges of the source and drain electrodes 19s and 19d opposed to each other with the gate electrode 13 sandwiched therebetween are stacked on the organic semiconductor layer 17.

In the first embodiment configured as described above, the organic semiconductor layer 17 is distinctively shaped relative to the gate electrode 13. That is, the organic semiconductor layer 17 is stacked above the gate electrode 13 in such a manner as to cover the gate electrode 13 along the width thereof. In other words, when the semiconductor device 1 is seen in a plan view from the side of the source and drain electrodes 19s and 19d, both edges of the organic semiconductor layer 17 along the width of the gate electrode 13 are arranged more outward than the edges of the gate electrode 13.

The organic semiconductor layer 17 has a thick film portion 17-1 and thin film portions 17-2. The thick film portion 17-1 is arranged at the center along the width of the gate electrode 13. The thin film portions 17-2 are thinner than the thick film portion and arranged each at one end along the width of the gate electrode 13. That is, the thick film portion 17-1 of the organic semiconductor layer 17 is arranged above the gate electrode 13 and along the direction in which the gate electrode 13 extends and has a thickness t1. On the other hand, each of the thin film portions 17-2 extends from the thick film portion 17-1 toward one side along the width of the gate electrode 13. The thickness of each of the thin film portions 17-2 is t2 that is smaller than t1 of the thick film portion 17-1.

Here, the area in which the thick film portion 17-1 is arranged is limited to that above the gate electrode 13. The thick film portion 17-1 is stacked above the gate electrode 13 in such a manner as to fit within the width of the gate electrode 13. When the semiconductor device 1 is seen in a plan view from the side of the source and drain electrodes 19s and 19d, both edges of the thick film portion 17-1 of the organic semiconductor layer 17 along the width of the gate electrode 13 are aligned with or located more inward than the edges of the gate electrode 13. A spacing d1 between each of the edges of the gate electrode 13 and the associated edge of the thick film portion is equal to or greater than 0 (d1≧0).

On the other hand, the area in which the thin film portions 17-2 are arranged reaches beyond the width of the gate electrode 13. When the semiconductor device 1 is seen in a plan view from the side of the source and drain electrodes 19s and 19d, both edges of the thin film portions 17-2 of the organic semiconductor layer 17 along the width of the gate electrode 13 are located more outward than the edges of the gate electrode 13. A spacing d2 between each of the edges of the gate electrode 13 and the associated edge of the thin film portions is equal to or greater than 0 (d2≧0).

Further, the thick film portion 17-1 and thin film portions 17-2 of the organic semiconductor layer 17 need only differ in thickness and have a difference in level.

The thickness t1 of the thick film portion 17-1 is sufficiently large to ensure that the interface of the organic semiconductor layer 17 with the gate insulating film 15, i.e., the channel region, will not be damaged in the process step operable to form the overlying layers of the semiconductor device 1. The thickness t1 is equal to or greater than that of four to five molecular layers of the material making up the organic semiconductor layer 17. Therefore, the thickness t1 is, for example, 30 nm or more and preferably 50 nm or more, although depending on the material making up the organic semiconductor layer 17. On the other hand, the thickness t1 of the thick film portion 17-1 need not be a fixed value so long as this thickness falls within the above range. The thick film portion 17-1 may have a difference in level or be partially tapered.

On the other hand, the thickness t2 of the thin film portions 17-2 is preferably small to the extent that the organic semiconductor layer 17 functions as such. The thickness t2 of the thin film portions is equal to or greater than that of one or more molecular layers of the material making up the organic semiconductor layer 17. On the other hand, the thickness t2 of the thin film portions 17-2 need not be a fixed value. The thin film portions 17-2 may have a difference in level in such a manner as to thin toward their end portions or be partially tapered. It should be noted, however, that the areas adjacent to the thick film portion 17-1 should preferably be thin.

It should be noted that the organic semiconductor layer 17 need only have the above cross-sectional shape where the source and drain electrodes 19s and 19d are stacked on the organic semiconductor layer 17 and where the organic semiconductor layer 17 is sandwiched between the source and drain electrodes 19s and 19d. Therefore, the areas of the organic semiconductor layer 17 on the side of the source and drain electrodes 19s and 19d need not have a cross-section with a difference in level.

On the other hand, each of the source and drain electrodes 19s and 19d is stacked at least on one of the thin film portions 17-2 of the organic semiconductor layer 17 along the width of the gate electrode 13. In order to prevent damage to a channel region ch during the subsequent process steps, the source and drain electrodes 19s and 19d should preferably be provided in such a manner as to cover the thin film portions 17-2 on the channel region ch. Therefore, the source and drain electrodes 19s and 19d should preferably be stacked in such a manner as to reach the thick film portion 17-1 of the organic semiconductor layer 17. In order to reduce the parasitic capacitance between the gate electrode 13 and the source and drain electrodes 19s and 19d, on the other hand, the overlapping width between the source and drain electrodes 19s and 19d and the thick film portion 17-1 of the organic semiconductor layer 17 should preferably be small. Therefore, the edges of the source and drain electrodes 19s and 19d should most preferably be aligned with the edges of the gate electrode 13.

A detailed description will be given below of the materials making up the members of the semiconductor device described above in sequence from the lowermost layer upward.

### <Substrate 11>

The substrate 11 need only have at least an insulating surface, and a variety of materials including glass, plastic and metal foil and paper may be used as the substrate 11. In the case of a plastic substrate, polyether sulphone, polycarbonate, polyimides, polyamides, polyacetals, polyethylene terephthalate, polyethylene naphthalate, polyethylether ketone and polyolefin can be, for example, used. In the case of a metal foil substrate, metal foil such as aluminum, nickel or stainless steel is laminated with an insulating resin for use. Further, a buffer layer or functional film such as barrier film may be formed on top of the substrate. The buffer layer provides improved adhesion and flatness. The barrier film provides improved gas barrier. A plastic or metal foil substrate is used as the substrate to provide flexible bendability.

### <Gate Electrode 13>

A metal or organic metallic material is used as the gate electrode 13. Among metals that can be used are gold (Au), platinum (Pt), palladium (Pd), silver (Ag), tungsten (W), tantalum (Ta), molybdenum (Mo), aluminum (Al), chromium (Cr), titanium (Ti), copper (Cu), nickel (Ni), indium (In), tin (Sn), manganese (Mn), ruthenium (Ru) and rubidium (Rb). These metallic materials are used alone or as a compound. Among organic metallic materials that can be used are (3,4-ethylenedioxythiophene)/poly (4-styrenesulfonate) [PEDOT/PSS] and tetrathiafulvalene/tetracyanoquinodimethane [TTF/TCNQ]. The film making up the gate electrode 13 described above can be formed not only by means of vacuum vapor deposition such as resistance heating vapor deposition or sputtering but also by means of coating described above using inks and pastes. The film may alternatively be formed by plating such as electroplating or electroless plating.

### <Gate Insulating Film 15>

An inorganic or organic insulating film may be used as the gate insulating film 15. Among inorganic insulating films that can be used are silicon oxide, silicon nitride, aluminum oxide, titanium oxide and hafnium oxide. Vacuum processes such as sputtering, resistance heating vapor deposition, physical vapor deposition (PVD) and chemical vapor deposition (CVD) are used to form an inorganic insulating film. Further, these inorganic insulating films are formed by the sol-gel method that uses a solution containing a raw material dissolved therein. On the other hand, among organic insulating films that can be used are polymer materials such as polyvinyl phenol, polyimide resins, novolak resins, cinnamate resins, acrylic resins, epoxy resins, styrene resins and polyparaxylylene. These organic insulating films are formed by means of coating or vacuum process. Among coating methods that can be used are spin coating, air doctor coating, blade coating, rod coating, knife coating, squeeze coating, reverse roll coating, transfer roll coating, gravure coating, kiss coating, cast coating, spray coating, slit orifice coating, calendar coating and immersion method. Among vacuum processes that can be used are chemical vapor deposition and vapor deposition polymerization.

### <Organic Semiconductor Layer 17>

Among materials that can be as the organic semiconductor layer 17 are as follows:
polypyrrole and substituted polypyrrole
polythiophene and substituted polythiophene
isothianaphthenes such as polyisothianaphthene
thienylenevinylenes such as polythienylenevinylene
poly(p-phenylenevinylenes) such as poly(p-phenylenevinylene)
polyaniline and substituted polyaniline
polyacetylenes
polydiacetylenes
polyazulenes
polypyrenes
polycarbazoles
polyselenophenes
polyfurans
poly (p-phenylenes)
polyindoles
polypyridazines
polymers such as polyvinylcarbazole, polyphenylene sulfide and polyvinylene sulfide and polycyclic condensation products
oligomers having the same repeat units as the polymers in the above materials
acenes such as naphthacene, pentacene, hexacene, heptacene, dibenzopentacene, tetrabenzopentacene, pyrene, dibenzopyrene, chrysene, perylene, coronene, terylene, ovalene, quaterrylene and circumanthracene, derivatives (e.g., triphenodioxazine, triphenodithiazine, hexacene-6,15-quinone, perixanthenoxanthene) obtained by substituting part of the carbon of acenes by an atom such as N, S or O or a functional group such as a carbonyl group, and derivatives obtained by substituting the hydrogen thereof by other functional group
metallophthalocyanines
tetrathiafulvalene and tetrathiafulvalene derivatives
tetrathiapentalene and tetrathiapentalene derivatives
naphthalene tetracarboxylic acid diimides such as naphthalene 1,4,5,8- tetracarboxylic acid diimide, N,N′-bis(4-trifluoromethylbenzyl)naphthalene 1,4,5,8-tetracarboxylic acid diimide, N,N′-bis(1H, 1H-perfluoroctyl), N,N′-bis(1-H, 1H-perfluorobutyl), N,N′-dioctylnaphthalene 1,4,5,8- tetracarboxylic acid diimide derivative and naphthalene 2,3,6,7 tetracarboxylic acid diimides
condensed ring tetracarboxylic acid diimides such as anthracene 2,3,6,7-tetracarboxylic acid diimides including anthracene tetracarboxylic acid diimide
fullerenes such as C60, C70, C76, C78 and C84 and their derivatives
carbon nanotubes such as SWNT
dyes such as merocyanine dyes and hemicyanine dyes and their derivatives

A film made of one of the above organic semiconductor materials is formed by means of coating or vacuum process. Among coating methods that can be used are spin coating, air doctor coating, blade coating, rod coating, knife coating, squeeze coating, reverse roll coating, transfer roll coating, gravure coating, kiss coating, cast coating, spray coating, slit orifice coating, calendar coating and immersion method. Among vacuum processes that can be used are vacuum vapor deposition methods such as resistance heating vacuum deposition and sputtering.

<Source/Drain Electrodes 19s and 19d>

The source and drain electrodes 19s and 19d are made of the same material as the gate electrode 13. These electrodes may be made of any material so long as the material forms an ohmic contact particularly with the organic semiconductor layer 17.

### <Manufacturing Method (1)>

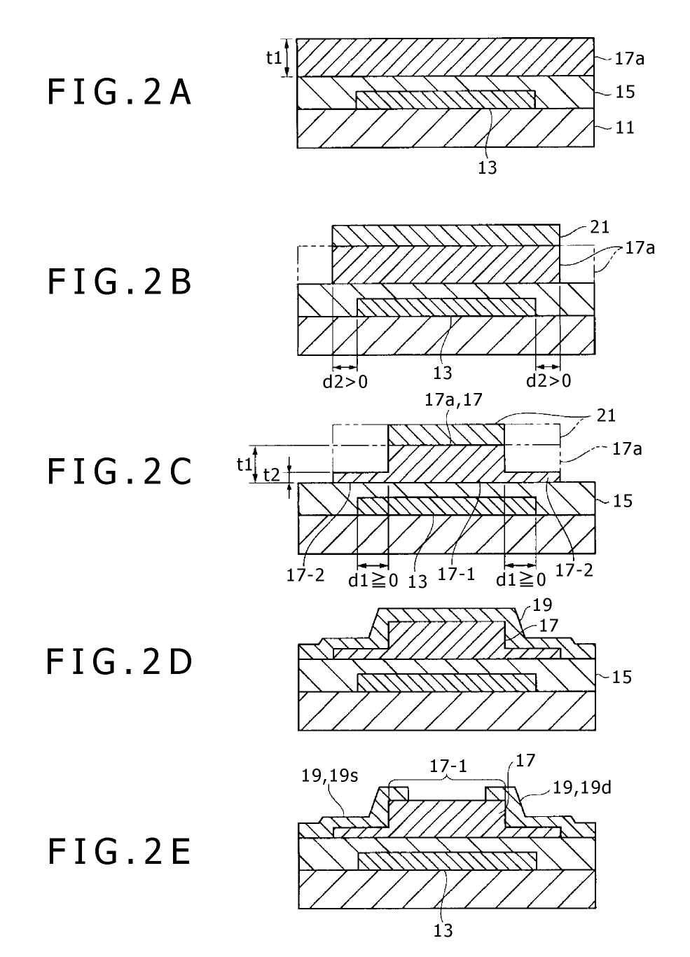

A description will be given next of the method of forming a resist pattern directly on top of an organic semiconductor material film as a first example of the manufacturing method of the semiconductor device 1 according to the first embodiment with reference to the cross-sectional process diagrams shown in FIGS. 2A to 2E.

First, the gate electrode 13 is formed on top of the substrate 11 as illustrated in FIG. 2A. Here, an electrode material film making up the gate electrode is formed. Next, a resist pattern (not shown) is formed on top of the electrode material film by means of photolithography. Then, the resist pattern is used as a mask to pattern-etch the electrode material film, thus providing the gate electrode 13. Following the etching, the resist pattern is removed.

Next, the gate insulting film 15 is formed across the entire substrate 11 in such a manner as to cover the gate electrode 13. Here, the gate electrode 13 made of polyvinyl phenol (PVP) is formed, for example, by means of spin coating.

Next, an organic semiconductor material film 17a is formed on top of the gate insulating film 15. Here, the same film 17a is formed using an organic semiconductor material highly resistant to organic solvents. For example, therefore, the organic semiconductor material film 17a made of poly-3-hexylthiophene (P3HT) is formed to the thickness t1 (e.g., 50 nm).

Then, a resist pattern 21 is formed on top of the organic semiconductor material film 17a by means of photolithography as illustrated in FIG. 2B. The resist pattern 21 is in the form of an island covering the gate electrode 13 and formed in the element region. It should be noted that a resist material made of a fluorine-based resin is preferred for use as the resist pattern 21 formed in this step. This keeps damage to the organic semiconductor material film 17a to a minimum, making it possible to perform the development process adapted to selectively remove the resist material from the organic semiconductor material film 17a. Further, a positive resist should preferably be used so that the exposed areas are removed during the development process.

Next, the organic semiconductor material film 17a is pattern-etched using the resist pattern 21 as a mask, thus patterning the same film 17a into the form of an island covering the gate electrode 13 along the width thereof. Here, it is important to arrange both edges of the organic semiconductor material film 17a along the width of the gate electrode 13 more outward than the edges of the gate electrode 13 and to ensure that the planar spacing d2 between each of the edges of the gate electrode 13 and the associated edge of the organic semiconductor material film 17a is greater than 0 (d2>0).

The etching of the organic semiconductor material film 17a formed as described above should preferably be accomplished by anisotropic etching. As an example of such anisotropic etching, the same film 17a is etched, for example, by means of reactive ion etching using oxygen as an etching gas.

Next, the resist pattern 21 is exposed for the second time using a halftone mask (additional exposure) and developed as illustrated in FIG. 2C. As a result, both sides of the resist pattern 21 along the width of the gate electrode 13 are patterned and removed, thus thinning the same pattern 21. At this time, when a positive resist is used for the resist pattern 21, both sides of the same pattern 21 along the width of the gate electrode 13 are exposed for the second time, followed by removal of the exposed areas during the development process.

Next, the upper portion of the organic semiconductor material film 17a is etched using the thinned resist pattern 21 as a mask. Here, it is important to leave the organic semiconductor material film 17a unremoved to have the thickness t2 on both sides along the width of the gate electrode 13 following the etching. Further, the thick film portion 17-1 of the organic semiconductor material film 17a maintained constant at the initial thickness t1 is left unremoved to fit within the width of the gate electrode 13 covered with the resist pattern 21. By doing so, it is important to ensure that the planar spacing d1 between each of the edges of the gate electrode 13 and the associated edge of the thick film portion 17-1 is equal to or greater than 0 (d1≧0). The etching of the organic semiconductor material film 17a formed as described above should preferably be accomplished similarly by anisotropic etching.

As a result of the above steps, the organic semiconductor layer 17 is formed on top of the gate insulating film 15 in such a manner as to have the thick film portion 17-1 at the center along the width of the gate electrode 13 and the thin film portions 17-2, thinner than the thick film portion 17-1, each at one end along the width of the gate electrode 13.

It should be noted that the remaining resist pattern 21 is selectively dissolved and removed from the organic semiconductor layer 17 following the etching. On the other hand, the organic semiconductor layer 17 can also be patterned by laser-machining the organic semiconductor material film 17a without using the resist pattern 21. In this case, the organic semiconductor layer 17 can be patterned into a form having the two film thicknesses t1 and t2 by adjusting the laser output and other parameters and controlling the depth of machining of the organic semiconductor material film 17a.

After the above step, an electrode material film 19 is formed on top of the gate insulating film 15 in such a manner as to cover the organic semiconductor layer 17 as illustrated in FIG. 2D. Here, a material that forms an excellent ohmic contact with the organic semiconductor layer 17 is selected from among the materials listed above, and the film is formed using the selected material, for example, by means of vacuum vapor deposition.

Next, the electrode material film 19 is patterned as illustrated in FIG. 2E, thus forming the source and drain electrodes 19s and 19d. Here, a resist pattern (not shown) is formed on top of the electrode material film 19 by means of photolithography. Then, the resist pattern is used as a mask to pattern-etch the electrode material film, thus providing the source and drain electrodes 19s and 19d. Here, it is important to stack the source and drain electrodes 19s and 19d on the thin film portions 17-2 of the organic semiconductor layer 17 in such a manner that the edges of the source and drain electrodes 19s and 19d reach at least the edges of the gate electrode 13 along the width thereof. At this time, the end portions of the source and drain electrodes 19s and 19d need not be formed to such an extent as to lie over the thick film portion 17-1 of the organic semiconductor layer 17. In order to reduce the parasitic capacitance between the gate electrode 13 and the source and drain electrodes 19s and 19d, on the other hand, the overlapping width between the source and drain electrodes 19s and 19d and the thick film portion 17-1 of the organic semiconductor layer 17 should preferably be small.

The pattern etching of the electrode material film 19 described above can be accomplished without damaging the organic semiconductor layer 17 by using a water-soluble etchant. The resist pattern is removed following the pattern etching.

The above process steps provide the semiconductor device 1 having the bottom gate and top contact structure described with reference to FIGS. 1A and 1B and including a thin film transistor.

### <Manufacturing Method (2)>

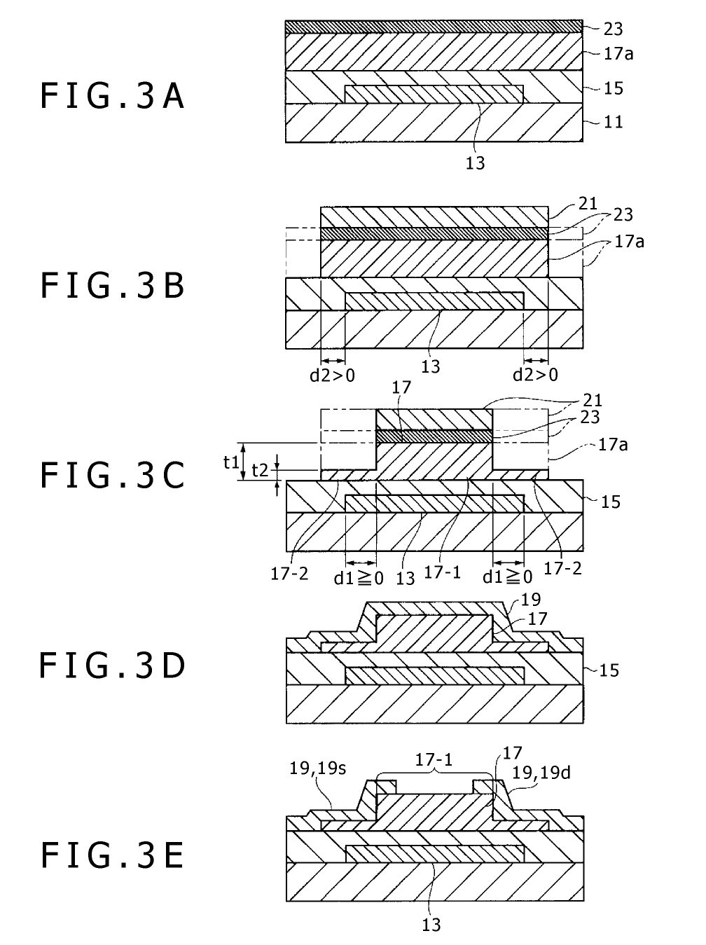

A description will be given next of the method of forming a resist pattern above an organic semiconductor material film with a buffer layer therebetween as a second example of the manufacturing method of the semiconductor device 1 according to the first embodiment with reference to the cross-sectional process diagrams shown in FIGS. 3A to 3E.

First, the gate electrode 13 is formed on top of the substrate 11 as illustrated in FIG. 3A. Next, the gate insulating film 15 made of PVP is formed in such a manner as to cover the gate electrode 13. Further, the organic semiconductor material film 17a is formed on top of the gate insulating film 15. The process steps up to this point are performed in the same manner as described in the first example with reference to FIG. 2A.

It should be noted, however, that an organic semiconductor material particularly highly resistant to organic solvents need not be used as the organic semiconductor material film 17a formed in this step. It is only necessary to use an organic semiconductor material that provides the properties suitable for the semiconductor device formed in this step. Therefore, the organic semiconductor material film 17a made of pentacene is formed to the thickness t1 (e.g., 50 nm), for example, by means of vacuum vapor deposition.

Still further, a metal buffer layer 23 is formed in this step on top of the organic semiconductor material film 17a. The metal buffer layer 23 is formed as a buffer layer that permits etching without damaging the organic semiconductor material film 17a. The metal buffer layer 23 is made, for example, of gold, aluminum, copper or other material and formed by means of vacuum vapor deposition.

Next, the resist pattern 21 is formed on top of the metal buffer layer 23 by means of photolithography as illustrated in FIG. 3B. As with the first example, the resist pattern 21 is in the form of an island covering the gate electrode 13 and formed in the element region.

It should be noted, however, that the resist pattern 21 formed in this step is formed on top of the metal buffer layer 23. As a result, possible damage to the organic semiconductor material film 17a need not be considered. Therefore, a resist material offering excellent patternability can be used.

Next, the metal buffer layer 23 is pattern-etched using the resist pattern 21 as a mask. At this time, wet etching is performed using a water-soluble etchant, thus pattern-etching only the metal buffer layer 23 without damaging the organic semiconductor material film 17a.

Further, as with the first example, the organic semiconductor material film 17a is etched using the metal buffer layer 23 as a mask, with the resist pattern 21 stacked, thus patterning the same film 17a into the form of an island covering the gate electrode 13 along the width thereof. Still further, it is important to arrange both edges of the organic semiconductor material film 17a, patterned in the form of an island, along the width of the gate electrode 13 more outward than the edges of the gate electrode 13 and to ensure that the spacing d2 between each of the edges of the gate electrode 13 and the associated edge of the organic semiconductor material film 17a is greater than 0 (d2>0).

The etching of the organic semiconductor material film 17a formed as described above should preferably be accomplished by anisotropic etching as with the first example. That is, the same film 17a is etched, for example, by means of reactive ion etching using oxygen as an etching gas.

Next, the resist pattern 21 is exposed for the second time (additional exposure) and developed as illustrated in FIG. 3C. As a result, both sides of the resist pattern 21 along the width of the gate electrode 13 are patterned and removed, thus thinning the same pattern 21.

Next, the metal buffer layer 23 is pattern-etched using the thinned resist pattern 21 as a mask. Further, the upper portion of the organic semiconductor material film 17a is etched. Here, it is important to leave the organic semiconductor material film 17a unremoved to have the thickness t2 following the etching. Further, it is important to leave the thick film portion 17-1, maintained constant at the initial thickness t1, unremoved to fit within the width of the gate electrode 13 in the organic semiconductor material film 17a covered with the resist pattern 21, thus ensuring that the spacing d1 between each of the edges of the gate electrode 13 and the associated edge of the thick film portion 17-1 is equal to or greater than 0 (d1≧0). The etching of the organic semiconductor material film 17a formed as described above should preferably be accomplished by anisotropic etching.

As a result of the above steps, the organic semiconductor layer 17 is formed on top of the gate insulating film 15 in such a manner as to have the thick film portion 17-1 at the center along the width of the gate electrode 13 and the thin film portions 17-2, thinner than the thick film portion 17-1, each at one end along the width of the gate electrode 13.

Following the etching, wet etching is performed using a water-soluble etchant, thus etching and removing the metal buffer layer 23 and thereby removing the resist pattern 21 remaining on the metal buffer layer 23.

After the above step, the source and drain electrodes are formed in the same manner as described in the first example with reference to FIGS. 2D and 2E.

That is, the electrode material film 19 is formed first on top of the gate insulating film 15 in such a manner as to cover the organic semiconductor layer 17 as illustrated in FIG. 3D. Here, a material that forms an excellent ohmic contact with the organic semiconductor layer 17 is selected from among the materials listed above, and the film is formed using the selected material, for example, by means of vacuum vapor deposition.

Next, the electrode material film 19 is patterned as illustrated in FIG. 3E, thus forming the source and drain electrodes 19s and 19d. Here, a resist pattern (not shown) is formed on top of the electrode material film 19 by means of photolithography. Then, the resist pattern is used as a mask to pattern-etch the electrode material film, thus providing the source and drain electrodes 19s and 19d. Here, it is important to stack the source and drain electrodes 19s and 19d on the thin film portions 17-2 of the organic semiconductor layer 17 in such a manner that the edges of the source and drain electrodes 19s and 19d reach at least the edges of the gate electrode 13 along the width thereof. At this time, the end portions of the source and drain electrodes 19s and 19d need not be formed to such an extent as to lie over the thick film portion 17-1 of the organic semiconductor layer 17. In order to reduce the parasitic capacitance between the gate electrode 13 and the source and drain electrodes 19s and 19d, on the other hand, the overlapping width between the source and drain electrodes 19s and 19d and the thick film portion 17-1 of the organic semiconductor layer 17 should preferably be small. Etching is performed here using a water-soluble etchant, thus pattern-etching the electrode material film 19 without adversely affecting the organic semiconductor layer 17. The resist pattern is removed following the pattern etching.

The above process steps provide the semiconductor device 1 having the bottom gate and top contact structure described with reference to FIGS. 1A and 1B and including a thin film transistor.

### <Manufacturing Method (3)>

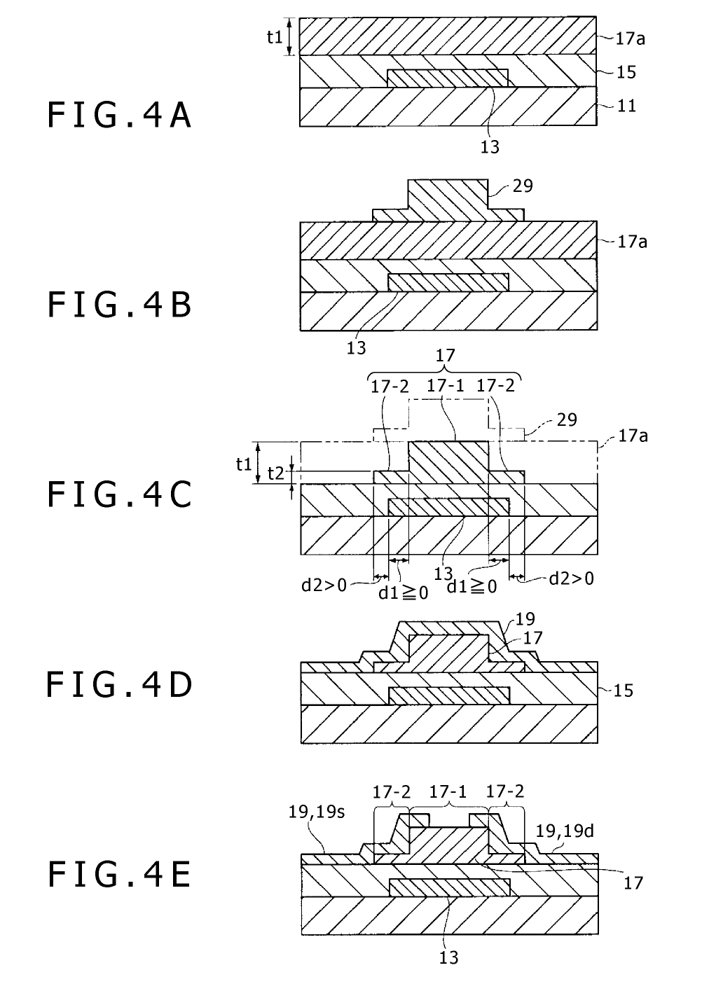

A description will be given next of the method of transferring the shape of a resist pattern to an organic semiconductor material film as a third example of the manufacturing method of the semiconductor device 1 according to the first embodiment with reference to the cross-sectional process diagrams shown in FIGS. 4A to 4E.

First, the gate electrode 13 is formed on top of the substrate 11 as illustrated in FIG. 4A. Next, the gate insulating film 15 made of PVP is formed in such a manner as to cover the gate electrode 13. Further, the organic semiconductor material film 17a is formed on top of the gate insulating film 15. The process steps up to this point are performed in the same manner as described in the first example with reference to FIG. 2A. That is, the organic semiconductor material film 17a is formed to the thickness t1 (e.g., 50 nm) using an organic semiconductor material highly resistant to organic solvents such as poly(3-hexylthiophene) (P3HT) by means of spin coating.

Next, a resist pattern 29 is formed on top of the organic semiconductor material film 17a by means of photolithography as illustrated in FIG. 4B. Here, exposure using a halftone mask or two-step exposure is performed, thus exposing the resist film so that the edges and center of the gate electrode 13 along the width thereof are exposed to different extents. This process step provides the resist pattern 29 in the form of an island covering the gate electrode 13 along the width thereof and having the edges along the width of the gate electrode 13 thinner than the central portion.

It should be noted that a resist material made of a fluorine-based resin is preferred for use as the resist pattern 29 formed in this step as with the first example of the first embodiment. The organic semiconductor material film 17a can be developed without any damage by using a similar developing solution.

Next, the organic semiconductor material film 17a is pattern-etched from above the resist pattern 29 as illustrated in FIG. 4C, thus forming the organic semiconductor layer 17 where the same layer 17 overlaps the gate electrode 13. Here, the organic semiconductor material film 17a is anisotropically etched together with the resist pattern 29, thus transferring the shape of the resist pattern 29 to the organic semiconductor material film 17a.

As a result of the above steps, the organic semiconductor layer 17 is formed on top of the gate insulating film 15 in such a manner as to have the thick film portion 17-1 at the center along the width of the gate electrode 13 and the thin film portions 17-2, thinner than the thick film portion 17-1, each at one end along the width of the gate electrode 13.

Next, the organic semiconductor material film 17a is pattern-etched using the resist pattern 29 as a mask, thus patterning the same film 17a into the form of an island covering the gate electrode 13 along the width thereof. Here, it is important to arrange both edges of the organic semiconductor material film 17a, patterned in the form of an island, along the width of the gate electrode 13 more outward than the edges of the gate electrode 13 and to ensure that the planar spacing d2 between each of the edges of the gate electrode 13 and the associated edge of the organic semiconductor material film 17a is greater than 0 (d2>0).

The anisotropic etching described above is accomplished, for example, by reactive ion etching using oxygen as an etching gas. On the other hand, if the resist pattern 29 remains unremoved following the etching, the resist pattern 29 is selectively dissolved and removed from the organic semiconductor layer 17. It should be noted that the resist pattern 29 remaining unremoved only on the thick film portion at the center of the organic semiconductor layer 17 may be left unremoved and used as a protective film.

After the above step, the source and drain electrodes are formed in the same manner as described in the first example of the first embodiment.

That is, the electrode material film 19 is formed first on top of the gate insulating film 15 in such a manner as to cover the organic semiconductor layer 17 as illustrated in FIG. 4D. Here, a material that forms an excellent ohmic contact with the organic semiconductor layer 17 is selected from among the materials listed above, and the film is formed using the selected material, for example, by means of vacuum vapor deposition.

Next, the electrode material film 19 is patterned as illustrated in FIG. 4E, thus forming the source and drain electrodes 19s and 19d. Here, a resist pattern (not shown) is formed on top of the electrode material film 19 by means of photolithography. Then, the resist pattern is used as a mask to pattern-etch the electrode material film, thus providing the source and drain electrodes 19s and 19d. Here, it is important to stack the source and drain electrodes 19s and 19d on the thin film portions 17-2 of the organic semiconductor layer 17 in such a manner that the edges of the source and drain electrodes 19s and 19d reach at least the edges of the gate electrode 13 along the width thereof. At this time, the end portions of the source and drain electrodes 19s and 19d need not be formed to such an extent as to lie over the thick film portion 17-1 of the organic semiconductor layer 17. In order to reduce the parasitic capacitance between the gate electrode 13 and the source and drain electrodes 19s and 19d, on the other hand, the overlapping width between the source and drain electrodes 19s and 19d and the thick film portion 17-1 of the organic semiconductor layer 17 should preferably be small. Etching is performed here using a water-soluble etchant, thus pattern-etching the electrode material film 19 without adversely affecting the organic semiconductor layer 17. The resist pattern is removed following the pattern etching.

The above process steps provide the semiconductor device 1 having the bottom gate and top contact structure described with reference to FIGS. 1A and 1B and including a thin film transistor.

The semiconductor device 1 configured as illustrated in FIGS. 1A and 1B obtained by the above process steps is an organic thin film transistor having a bottom gate and top contact structure. The same device 1 has the source and drain electrodes 19s and 19d stacked on top of both edges of the organic semiconductor layer 17 along the width of the gate electrode 13. This provides solid contact between the organic semiconductor layer 17 and the source and drain electrodes 19s and 19d. Further, both edges of the organic semiconductor layer 17 along the width of the gate electrode 13 in particular are formed as the thin film portions 17-2, with the end portions of the source and drain electrodes 19s and 19d stacked on top of the thin film portions 17-2. This maintains constant the thickness t1 at the center of the area of the organic semiconductor layer 17 stacked above the gate electrode 13, i.e., the thickness t1 of the organic semiconductor layer 17 above the channel region ch. At the same time, this thins the organic semiconductor layer 17 at both edges of the channel region ch, thus providing reduced resistance between the channel region ch and the source and drain electrodes 19s and 19d.

As described above, the semiconductor device 1 according to the first embodiment provides reduced resistance between the channel region and the source and drain electrodes 19s and 19d irrespective of the thickness of the area of the organic semiconductor layer 17 for the channel region ch despite having a bottom gate and top contact structure. This makes it possible to reduce the contact resistance (injection resistance) of the source and drain electrodes 19s and 19d to the channel region ch while at the same time securing an appropriate film quality of the area of the organic semiconductor layer 17 for the channel region ch, thus contributing to improved reliability and functionality of the semiconductor device 1.

### 2. SECOND EMBODIMENT

### <Configuration of the Semiconductor Device>

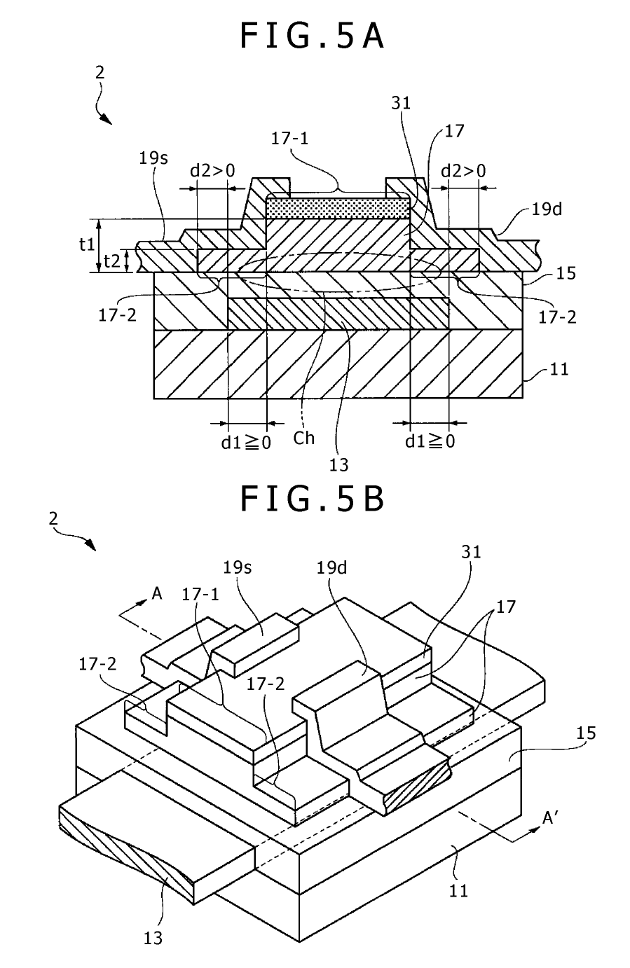

FIGS. 5A and 5B are cross-sectional and plan views illustrating the configuration of a semiconductor device 2 according to a second embodiment. The cross-sectional view illustrates the cross-section taken along line A-A′ in the plan view. The semiconductor device 2 shown in these views is configured in the same manner as the semiconductor device 1 according to the first embodiment except that an insulating protective film 31 is stacked on top of the thick film portion 17-1 of the organic semiconductor layer 17.

The protective film 31 specific to the second embodiment is designed to protect the channel region ch of the organic semiconductor layer 17 from possible damage during the formation of the pattern of the organic semiconductor layer 17. The protective film 31 is made of an organic or inorganic insulating material. The protective film 31 should preferably be made of an organic insulating material because the same film 31 can be etched in the same process step as the organic semiconductor material film making up the organic semiconductor layer 17. A fluorine resin can be used as such an organic insulating material.

In the second embodiment in particular, thanks to the protective film 31, the thickness t1 of the thick film portion 17-1 need only be large enough to provide a stable film quality of the organic semiconductor layer 17. As a result, possible damage to the organic semiconductor layer 17 during the formation of the overlying layers need not be considered. The thickness t1 of the thick film portion 17-1 of the organic semiconductor layer 17 is equal to or greater than that of four to five molecular layers of the material making up the organic semiconductor layer 17. Therefore, the thickness t1 is, for example, 30 nm or more and preferably 50 nm or more, although depending on the material making up the organic semiconductor layer 17. On the other hand, the thickness t1 of the thick film portion 17-1 need not be a fixed value so long as this thickness falls within the above range. The thick film portion 17-1 may have a difference in level or be partially tapered.

On the other hand, the thickness t2 of the thin film portions 17-2 is preferably small to the extent that the organic semiconductor layer 17 functions as such. The thickness t2 of the thin film portions is equal to or greater than that of one or more molecular layers of the material making up the organic semiconductor layer 17. On the other hand, the thickness t2 of the thin film portions 17-2 need not be a fixed value. The thin film portions 17-2 may have a difference in level in such a manner as to thin toward their end portions or be partially tapered. It should be noted, however, that the areas adjacent to the thick film portion 17-1 are preferably thin.

It should be noted that the thick film portion 17-1 and thin film portions 17-2 of the organic semiconductor layer 17 are arranged in the same manner relative to the gate electrode 13 as in the first embodiment.

On the other hand, if the source and drain electrodes 19s and 19d overlap the thick film portion 17-1 of the organic semiconductor layer 17, the edges of the same electrodes 19s and 19d are stacked above the thick film portion 17-1 of the organic semiconductor layer 17 with the protective film 31 therebetween. It should be noted, however, that the preferred example of the arrangement of the source and drain electrodes 19s and 19d is the same as in the first embodiment. That is, the source and drain electrodes 19s and 19d are stacked at least on top of the thin film portions 17-2 of the organic semiconductor layer 17 along the width of the gate electrode 13. In order to prevent damage to the channel region ch during the subsequent process steps, the source and drain electrodes 19s and 19d should preferably be provided in such a manner as to cover the thin film portions 17-2 on the channel region ch. Therefore, the source and drain electrodes 19s and 19d should preferably be stacked in such a manner as to reach the thick film portion 17-1 of the organic semiconductor layer 17. In order to reduce the parasitic capacitance between the gate electrode 13 and the source and drain electrodes 19s and 19d, on the other hand, the overlapping width between the source and drain electrodes 19s and 19d and the thick film portion 17-1 of the organic semiconductor layer 17 should preferably be small. Therefore, the edges of the source and drain electrodes 19s and 19d should most preferably be aligned with the edges of the gate electrode 13.

### <Manufacturing Method>

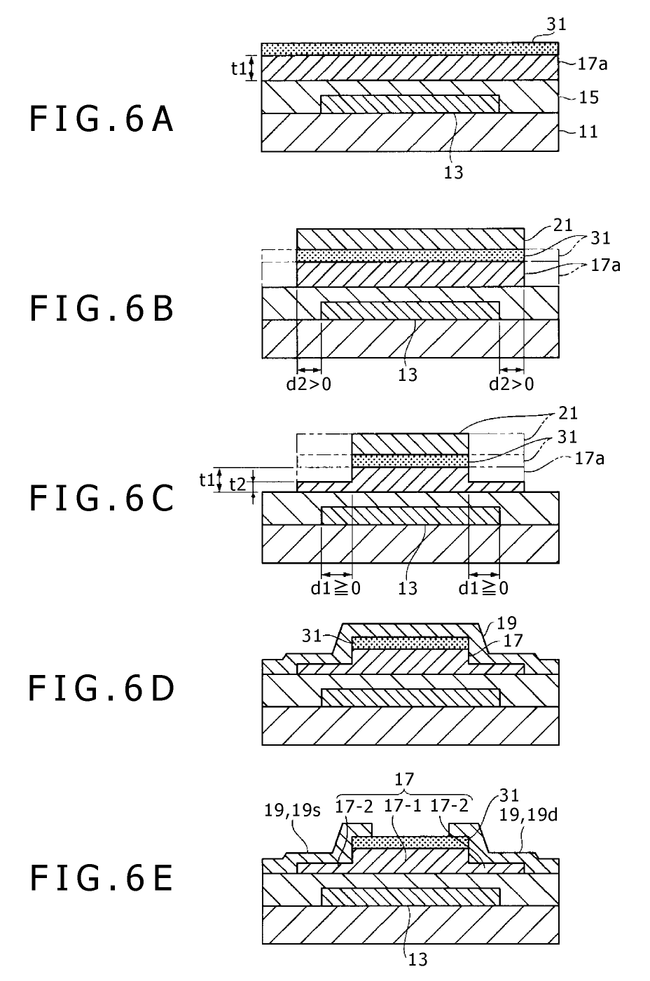

A description will be given below of the manufacturing method of the semiconductor device 2 according to the second embodiment configured as described above with reference to the cross-sectional process diagrams shown in FIGS. 6A to 6E.

First, the gate electrode 13 is formed on top of the substrate 11 as illustrated in FIG. 6A. Next, the gate insulating film 15 made of PVP is formed in such a manner as to cover the gate electrode 13. Further, the organic semiconductor material film 17a is formed on top of the gate insulating film 15. The process steps up to this point are performed in the same manner as described in the first example of the manufacturing method of the semiconductor device according to the first embodiment with reference to FIG. 2A.

It should be noted, however, that an organic semiconductor material particularly highly resistant to organic solvents need not be used as the organic semiconductor material film 17a formed in this step. It is only necessary to use an organic semiconductor material that provides the properties suitable for the semiconductor device formed in this step. Therefore, the organic semiconductor material film 17a made of pentacene is formed to the thickness t1 of 50 nm, for example, by means of vacuum vapor deposition.

Next, the protective film 31 is formed on top of the organic semiconductor material film 17a. The same film 31 is formed to protect the organic semiconductor material film 17a. The protective film 31 is made, for example, of a fluorine resin and formed by means of spin coating.

Next, the resist pattern 21 is formed on top of the protective film 31 by means of photolithography. The resist pattern 21 is in the form of an island covering the gate electrode 13 along the width thereof and formed in the element region as with the manufacturing methods according to the first embodiment.

It should be noted, however, that the resist pattern 21 formed in this step is formed on top of the protective film 31. As a result, possible damage to the organic semiconductor material film 17a need not be considered. Therefore, a resist material offering excellent patternability can be used.

Next, the protective film 31 and organic semiconductor material film 17a are pattern-etched using the resist pattern 21 as a mask, thus patterning the protective film 31 and organic semiconductor material film 17a into the form of an island covering the gate electrode 13 along the width thereof. This forms a layered body made up of the organic semiconductor material film 17a and protective film 31 where the two films overlap the gate electrode 13. Here, the etching of at least the organic semiconductor material film 17a is accomplished by anisotropic etching. On the other hand, it is important to arrange both edges of the organic semiconductor material film 17a, patterned in the form of an island, along the width of the gate electrode 13 more outward than the edges of the gate electrode 13 and to ensure that the spacing d2 between each of the edges of the gate electrode 13 and the associated edge of the organic semiconductor material film 17a is greater than 0 (d2>0).

At this time, if the protective film 31 is made of an organic material such as a fluorine resin, the protective film 31 and organic semiconductor material film 17a are pattern-etched in the same process step. The etching of the protective film 31 and organic semiconductor material film 17a is accomplished by anisotropic dry etching. For example, the etching thereof is accomplished by means of reactive ion etching using oxygen as an etching gas. It should be noted that the pattern etching of the protective film 31 and that of the organic semiconductor material film 17a may be performed in different process steps.

Next, the resist pattern 21 is exposed for the second time (additional exposure) and developed as illustrated in FIG. 6C. As a result, both sides of the resist pattern 21 along the width of the gate electrode 13 are patterned and removed, thus thinning the same pattern 21.

Next, the protective film 31 is pattern-etched, and the upper portion of the organic semiconductor material film 17a is etched using the thinned resist pattern 21 as a mask. Here, it is important to leave the organic semiconductor material film 17a unremoved to have the thickness t2 following the etching as with the first example of the manufacturing method according to the first embodiment. Further, it is important to leave the thick film portion 17-1 of the organic semiconductor material film 17a, maintained constant at the initial thickness t1, unremoved to fit within the width of the gate electrode 13 covered with the resist pattern 21. It is also important to ensure that the spacing d1 between each of the edges of the gate electrode 13 and the associated edge of the thick film portion 17-1 is equal to or greater than 0 (d1≧0). The etching of the organic semiconductor material film 17a formed as described above should preferably be accomplished by the same anisotropic etching method as used earlier.

As a result of the above steps, the organic semiconductor layer 17 is formed on top of the gate insulating film 15 in such a manner as to have the thick film portion 17-1 at the center along the width of the gate electrode 13 and the thin film portions 17-2, thinner than the thick film portion 17-1, each at one end along the width of the gate electrode 13. Further, the protective film 31 is stacked on top of the thick film portion 17-1 of the organic semiconductor layer 17. It should be noted that the remaining resist pattern 21 is selectively dissolved and removed from the organic semiconductor layer 17 and protective film 31 following the etching. On the other hand, the organic semiconductor layer 17 and protective film 31 can also be patterned by laser-machining the organic semiconductor material film 17a and protective film 31 without using the resist pattern 21. In this case, the organic semiconductor layer 17 can be patterned into a form having the two film thicknesses t1 and t2 by adjusting the laser output and other parameters and controlling the machining depth.

After the above step, the source and drain electrodes are formed in the same manner as described in the examples according to the first embodiment.

That is, the electrode material film 19 is formed first on top of the gate insulating film 15 in such a manner as to cover the organic semiconductor layer 17 and protective film 31 as illustrated in FIG. 6D. Here, a material that forms an excellent ohmic contact with the organic semiconductor layer 17 is selected from among the materials listed in the first embodiment, and the film is formed using the selected material, for example, by means of vacuum vapor deposition.

Next, the electrode material film 19 is patterned as illustrated in FIG. 6E, thus forming the source and drain electrodes 19s and 19d. Here, a resist pattern (not shown) is formed on top of the electrode material film 19 by means of photolithography. Then, the resist pattern is used as a mask to pattern-etch the electrode material film, thus providing the source and drain electrodes 19s and 19d. In this case, it is important to stack the source and drain electrodes 19s and 19d on the thin film portions 17-2 of the organic semiconductor layer 17 in such a manner that the edges of the source and drain electrodes 19s and 19d reach at least the edges of the gate electrode 13 along the width thereof. At this time, the end portions of the source and drain electrodes 19s and 19d need not be formed to such an extent as to lie over the thick film portion 17-1 of the organic semiconductor layer 17. In order to reduce the parasitic capacitance between the gate electrode 13 and the source and drain electrodes 19s and 19d, on the other hand, the overlapping width between the source and drain electrodes 19s and 19d and the thick film portion 17-1 of the organic semiconductor layer 17 should preferably be small. Etching is performed here using a water-soluble etchant, thus pattern-etching the electrode material film 19 without adversely affecting the organic semiconductor layer 17. The resist pattern is removed following the pattern etching.

The above process steps provide the semiconductor device 2 having the bottom gate and top contact structure described with reference to FIGS. 5A and 5B and including a thin film transistor.

The semiconductor device 2 configured as illustrated in FIGS. 5A and 5B obtained by the above process steps is an organic thin film transistor having a bottom gate and top contact structure, thus offering solid contact between the organic semiconductor layer 17 and the source and drain electrodes 19s and 19d. Further, both edges of the organic semiconductor layer 17 along the width of the gate electrode 13 are formed as the thin film portions 17-2, with the end portions of the source and drain electrodes 19s and 19d stacked on top of the thin film portions 17-2, as with the first embodiment. This maintains constant the thickness t1 of the central portion of the organic semiconductor layer 17 above the channel region ch. At the same time, this thins the organic semiconductor layer 17 at both edges of the channel region ch, thus providing reduced resistance between the channel region ch and the source and drain electrodes 19s and 19d.

In the semiconductor device 2 according to the second embodiment, the thick film portion 17-1 of the organic semiconductor layer 17 has its top surface covered with the protective film 31. This keeps the thick film portion 17-1 of the organic semiconductor layer 17 free from damage during the manufacturing process, thus securing an appropriate film quality of the channel region ch.

As described above, the semiconductor device 2 according to the second embodiment provides reduced contact resistance (injection resistance) of the source and drain electrodes 19s and 19d to the channel region ch while at the same time securing an appropriate film quality of the channel region ch in an even more positive manner than in the first embodiment. As a result, despite having a top contact structure whose contact resistance has been hitherto considered difficult to reduce although offering solid contact between the source and drain electrodes 19s and 19d and the organic semiconductor layer 17, the semiconductor device 2 according to the second embodiment provides reduced contact resistance while at the same time maintaining the reliability, thus contributing to improved functionality.

### 3. THIRD EMBODIMENT

### <Configuration of the Semiconductor Device>

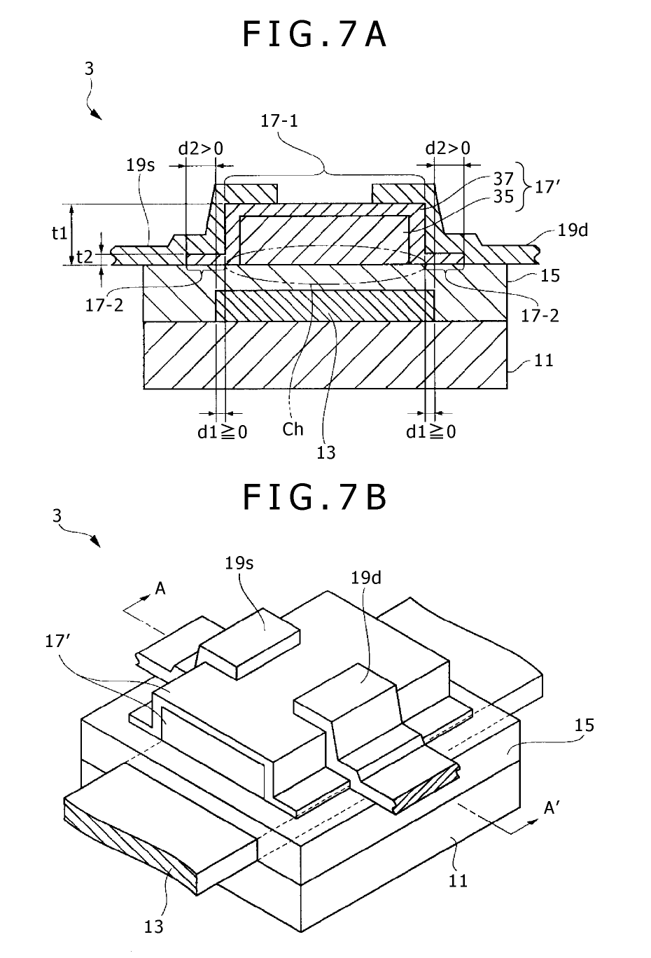

FIGS. 7A and 7B are cross-sectional and plan views illustrating the configuration of a semiconductor device 3 according to a third embodiment. The cross-sectional view illustrates the cross-section taken along line A-A′ in the plan view. The semiconductor device 3 shown in these views is configured in the same manner as the semiconductor device 1 according to the first embodiment except that an organic semiconductor layer 17′ has a two-layer structure.

The overall configuration of the organic semiconductor layer 17′ that includes first and second layers 35 and 37 is the same as that of the counterparts according to the first and second embodiments.

That is, the organic semiconductor layer 17′ including the first and second layers 35 and 37 has the thick film portion 17-1 at the center along the width of the gate electrode 13 and the thin film portions 17-2, thinner than the thick film portion 17-1, each at one end along the width of the gate electrode 13.

The thick film portion 17-1 includes two layers, the first layer 35 patterned to fit within the width of the gate electrode 13 and the second layer 37 covering the first layer 35. That is, the thickness t1 of the thick film portion 17-1 is the sum of the thicknesses of the first and second layers 35 and 37 and equal to or greater than that of four to five molecular layers of the organic semiconductor material making up the first and second layers 35 and 37. Therefore, the thickness t1 is, for example, 30 nm or more and preferably 50 nm or more, although depending on the material making up the first and second layers 35 and 37. On the other hand, the width of the thick film portion 17-1 is the sum of the widths of the first layer 35 and the second layer 37 formed on the side walls of the first layer 35 and fits within the width of the gate electrode 13. The spacing d1 between each of the edges of the gate electrode 13 and the associated edge of the thick film portion 17-1 is equal to or greater than 0 (d1≧0).

In contrast, each of the thin film portions 17-2 includes only the second layer 37. That is, the thickness t2 of the thin film portions 17-2 is equal to the thickness of the second layer 37, which is equal to or greater than that of one or more molecular layers of the material making up the second layer 37. On the other hand, the thickness t2 of the thin film portions 17-2 need not be a fixed value. The thin film portions 17-2 may have a difference in level in such a manner as to thin toward their end portions or be partially tapered. It should be noted, however, that the areas adjacent to the thick film portion 17-1 are preferably thin. On the other hand, the width of each of the thin film portions 17-2 is equal to that of the second layer 37 lying from the side wall of the first layer 35 to one side of the gate electrode 13. The spacing d2 between each of the edges of the gate electrode 13 and the associated edge of the thin film portions is greater than 0 (d2>0).

The first and second layers 35 and 37 should preferably be made of the same organic semiconductor material, but are not limited thereto.

### <Manufacturing Method>

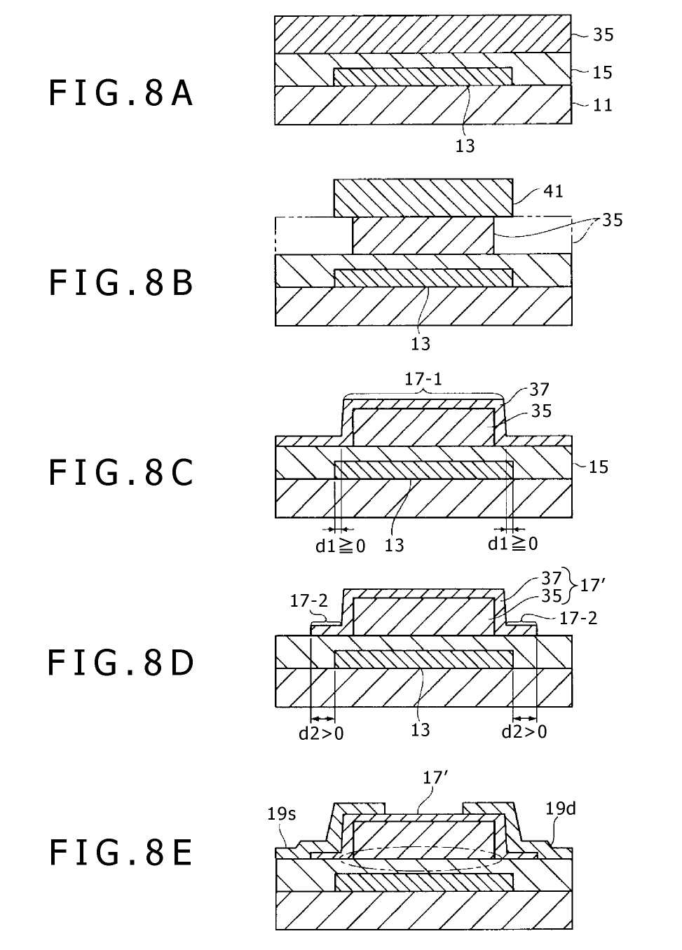

A description will be given below of the manufacturing method of the semiconductor device 3 according to the third embodiment with reference to the cross-sectional process diagrams shown in FIGS. 8A to 8E.

First, the gate electrode 13 is formed on top of the substrate 11 as illustrated in FIG. 8A. Next, the gate insulating film 15 made of PVP is formed in such a manner as to cover the gate electrode 13. Further, the first layer 35 of the organic semiconductor material film is formed on top of the gate insulating film 15. The process steps up to this point are performed in the same manner as described in the first example of the manufacturing method of the semiconductor device 1 according to the first embodiment with reference to FIG. 2A. That is, the first layer 35 of the organic semiconductor material film is formed using an organic semiconductor material highly resistant to organic solvents such as poly(3-hexylthiophene) (P3HT) by means of spin coating.

Next, a resist pattern 41 is formed on top of the first layer 35 of the organic semiconductor material film by means of photolithography as illustrated in FIG. 8B. The resist pattern 41 is, for example, roughly as wide as the gate electrode 13 and stacked in the form of an island above the gate electrode 13 in the element region.

It should be noted that a resist material made of a fluorine-based resin should preferably be used as the resist pattern 41 formed in this step as with the first example according to the first embodiment. The first layer 35 of the organic semiconductor material film can be developed without any damage by using a similar developing solution.

Next, the first layer 35 of the organic semiconductor material film is pattern-etched from above the resist pattern 41, thus etching the same layer 35 into the form of an island overlapping the gate electrode 13. At this time, the first layer 35 is isotropically overetched, thus patterning the first layer 35 to a width smaller than that of the gate electrode 13.

It should be noted that the remaining resist pattern 41 is selectively dissolved and removed from the first layer 35 of the organic semiconductor material film following the etching. On the other hand, the process step using a metal buffer layer described with reference to FIGS. 3 may be used to pattern the first layer 35 of the organic semiconductor material film. Further, the same layer 35 can also be patterned by laser-machining without using the resist pattern 41.

Next, the second layer 37 of the organic semiconductor material film is formed on top of the gate insulating film 15 in such a manner as to cover the patterned first layer 35 as illustrated in FIG. 8C. Here, the second layer 37 is formed thin to the extent that the same layer 37 is one or more molecular layers thick. At this time, the second layer 37 is formed so that the portions of the second layer 37 covering the side walls of the first layer 35 fit within the width of the gate electrode 13, that is, so that the spacing d1 between each of the edges of the thick film portion 17-1 made up of the first and second layers 35 and 37 and the associated edge of the gate electrode 13 is equal to or greater than 0 (d1≧0). Here, the second layer 37 is formed, for example, using the same organic semiconductor material highly resistant to organic solvents as used for the first layer 35 such as poly(3-hexylthiophene) (P3HT) by means of spin coating.

Next, the second layer 37 of the organic semiconductor material film is patterned into the form of an island covering the first layer 35 of the same film as illustrated in FIG. 8D. At this time, the second layer 37 is patterned so that the edges of the second layer 37 along the width of the gate electrode 13 are arranged more outward than the edges of the gate electrode 13. This ensures that the spacing d2 between each of the edges of the thin film portions 17-2 made up only of the second layer 37 and the associated edge of the gate electrode 13 is greater than 0 (d2>0). The patterning of the second layer 37 is conducted in the same manner as with the patterning of the first layer 35.

As a result, the organic semiconductor layer 17′ is obtained that is made up of the first and second layers 35 and 37.

After the above step, the source and drain electrodes 19s and 19d are formed with their edges stacked on top of the thin film portions 17-2 of the organic semiconductor layer 17′ by means of photolithography as illustrated in FIG. 8E as with the other embodiments described above.

The above process steps provide the semiconductor device 3 having the bottom gate and top contact structure described with reference to FIGS. 7A and 7B and including a thin film transistor.

The semiconductor device 3 configured as illustrated in FIGS. 7A and 7B obtained by the above process steps is a thin film transistor having a bottom gate and top contact structure, thus offering solid contact between the organic semiconductor layer 17′ and the source and drain electrodes 19s and 19d. Further, both edges of the organic semiconductor layer 17′ along the width of the gate electrode 13 are formed as the thin film portions 17-2, with the end portions of the source and drain electrodes 19s and 19d stacked on top of the thin film portions 17-2, as with the first and second embodiments. This maintains constant the thickness t1 of the central portion of the organic semiconductor layer 17′ above the channel region ch. At the same time, this thins the organic semiconductor layer 17′ at both edges of the channel region ch, thus providing reduced resistance between the channel region ch and the source and drain electrodes 19s and 19d.

In the semiconductor device 3 according to the third embodiment in particular, the organic semiconductor layer 17′ has a layered structure made up of the first layer 35 and the second layer 37 covering the first layer 35. The thin film portions 17-2 are made up only of the second layer 37. As a result, the thickness of the thin film portions 17-2 is well controllable to that of the second layer 37 at the time of its formation. This provides a smaller and well controllable spacing between the channel region ch and the source and drain electrodes 19s and 19d with the thin film portions 17-2 sandwiched therebetween, positively contributing to reduced contact resistance (injection resistance).

As described above, the semiconductor device 3 according to the third embodiment provides more reduced contact resistance (injection resistance) of the source and drain electrodes 19s and 19d to the channel region ch than in the first embodiment while at the same time securing an appropriate film quality of the channel region ch in an even more positive manner than in the first embodiment. As a result, despite having a top contact structure whose contact resistance has been hitherto considered difficult to reduce although offering solid contact between the source and drain electrodes 19s and 19d and the organic semiconductor layer 17′, the semiconductor device 3 according to the third embodiment provides reduced contact resistance without degrading the reliability, thus contributing to improved functionality.

### 4. FOURTH EMBODIMENT

### <Configuration of the Semiconductor Device>

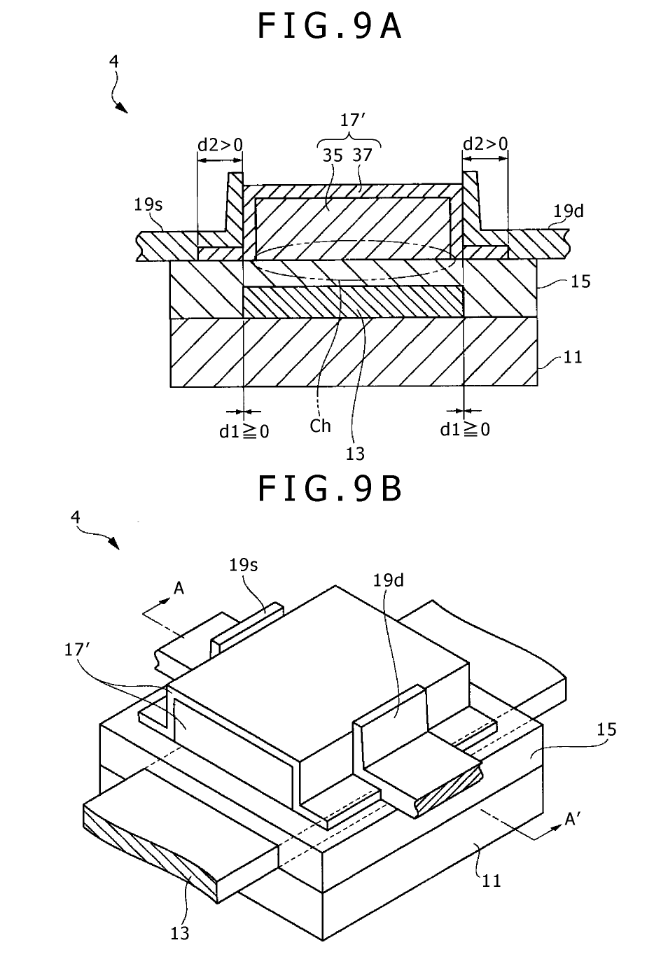

FIGS. 9A and 9B are cross-sectional and plan views illustrating the configuration of a semiconductor device 4 according to a fourth embodiment. The cross-sectional view illustrates the cross-section taken along line A-A′ in the plan view. The semiconductor device 4 shown in these views has the organic semiconductor layer 17′ with a two-layer structure as with the third embodiment. The semiconductor device 4 is configured in the same manner as the semiconductor device 3 according to the third embodiment except that the edges of the source and drain electrodes 19s and 19d are arranged in a self-aligned manner relative to the gate electrode 13.

That is, the edges of the source and drain electrodes 19s and 19d arranged with the gate electrode 13 sandwiched therebetween are aligned with the edges of the gate electrode 13 along the width thereof. The gate electrode 13 configured as described above can be obtained by backside exposure using the gate electrode 13 as described below.

### <Manufacturing Method>

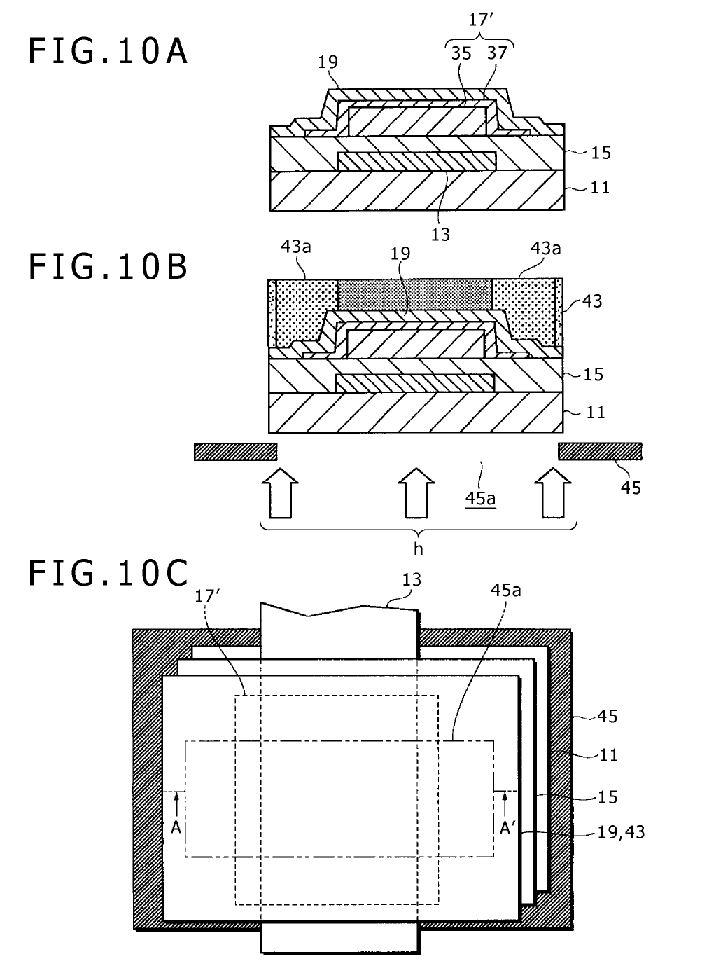

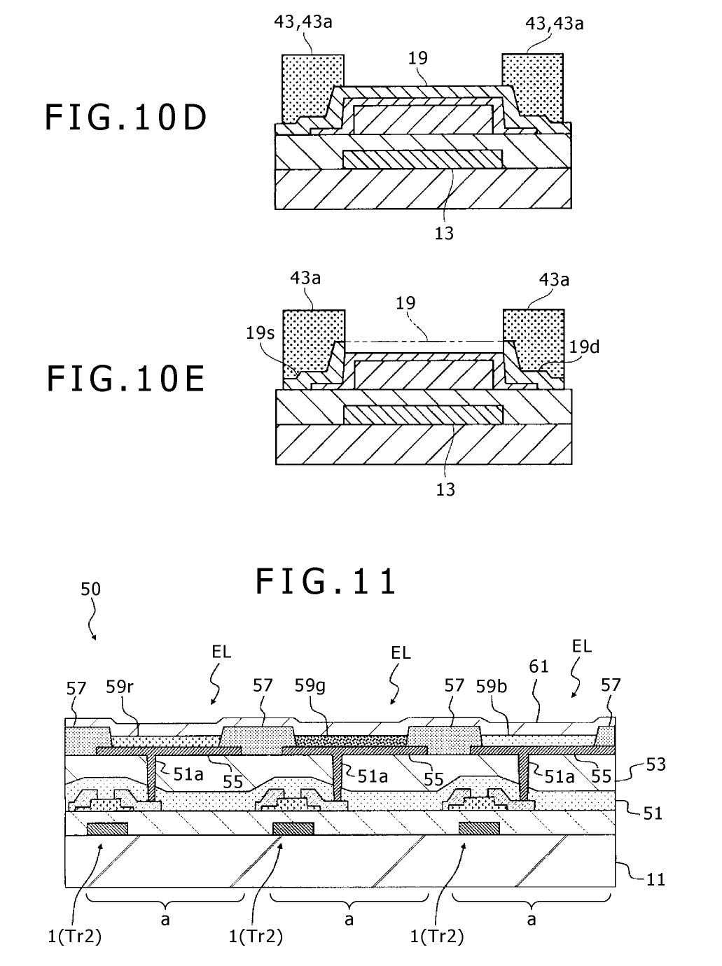

A description will be given below of the manufacturing method of the semiconductor device 4 according to the fourth embodiment with reference to the manufacturing process diagrams shown in FIGS. 10A to 10E.

First, the gate electrode 13 is formed on top of the substrate 11, followed by the gate insulating film 15 and organic semiconductor layer 17′ having a two-layer structure made up of the first and second layers 35 and 37 by following the same process steps as described in the third embodiment as illustrated in FIG. 10A. Then, the electrode material film 19 is formed first on top of the gate insulating film 15 in such a manner as to cover the organic semiconductor layer 17′. Here, a material that forms an excellent ohmic contact with the organic semiconductor layer 17′ is selected from among the materials listed in the first embodiment, and the film is formed using the selected material, for example, by means of vacuum vapor deposition.

The next process step is shown in the cross-sectional view of FIG. 10B and the plan view of FIG. 10C. The cross-sectional view illustrates the cross-section taken along line A-A′ in the plan view. As shown in these views, a negative resist film 43 is formed first on top of the electrode material film 19.

Then, the resist film 43 is exposed on the backside from the side of the substrate 11 using the gate electrode 13 as a mask. At this time, an exposure mask 45 is arranged on the side of the substrate 11, and exposure light h is irradiated via the exposure mask 45.

The exposure mask 45 has an opening portion 45a that intersects with the gate electrode 13. The opening portion 45a need only be configured so that the exposure light h is irradiated to pass by the gate electrode 13 on both sides. If the opening portion 45a is arranged to fit within the organic semiconductor layer 17′ in the direction of extension of the gate electrode 13 as illustrated, the width of the opening portion 45a serves as a channel width. This is preferred because the gate width is well controllable. On the other hand, if the opening portion 45a is arranged to fit outside the organic semiconductor layer 17′ in the direction of extension of the gate electrode 13, the width of the organic semiconductor layer 17′ serves as a channel width.

Thanks to the backside exposure via the exposure mask 45 as described above, the exposure light h is irradiated onto the areas of the resist film 43 not shielded from light by the gate electrode 13 in the opening portion 45a of the exposure mask 45, turning these areas into exposed portions 43a and hardening the resist material.

Next, the resist film 43 is developed as illustrated in FIG. 10D, thus leaving the exposed portions 43a unremoved on the electrode material film 19 as the resist pattern 43a. As a result, the resist pattern 43a is formed in a self-aligned manner relative to the gate electrode 13.

Next, the electrode material film 19 is pattern-etched using the resist pattern 43a as a mask as illustrated in FIG. 10E. This etches and removes the electrode material film 19 from the gate electrode 13, thus forming the source and drain electrodes 19s and 19d, made up of the electrode material film 19, in a self-aligned manner relative to the gate electrode 13.

The above process steps provide the semiconductor device 4 having the bottom gate and top contact structure described with reference to FIGS. 9A and 9B and including a thin film transistor.

The semiconductor device 4 configured as illustrated in FIGS. 9A and 9B obtained by the above process steps has the organic semiconductor layer 17′ with a two-layer structure as the same as the third embodiment. In the semiconductor device 4, the edges of the source and drain electrodes 19s and 19d are arranged in a self-aligned manner relative to the gate electrode 13. Therefore, the semiconductor device 4 provides not only the same advantageous effect as the third embodiment but also the following special advantageous effect.

That is, the semiconductor device 4 according to the fourth embodiment allows for effective reduction of the parasitic capacitance between the gate electrode 13 and the source and drain electrodes 19s and 19d thanks to the self-aligned arrangement of the edges of the source and drain electrodes 19s and 19d relative to the gate electrode 13, thus contributing to even more improved functionality than the semiconductor device according to the third embodiment.

It should be noted that, in the fourth embodiment, a description has been given of the self-aligned arrangement of the edges of the source and drain electrodes 19s and 19d relative to the gate electrode 13. However, the fourth embodiment may be combined with the configurations of the first or second embodiment. If combined with the fourth embodiment, the first or second embodiment can provide the additional advantageous effect obtained by the fourth embodiment.

### 5. FIFTH EMBODIMENT

### <Layer Configuration of the Display Device>

FIG. 11 is a configuration diagram of three pixels of a display device 50 to which the present disclosure is applied. The display device 50 includes the semiconductor device according to the present disclosure illustrated by way of example in one of the first to fourth embodiments. Here, the display device 50 includes, for example, the semiconductor device 1 described in the first embodiment, i.e., a thin film transistor having a bottom gate and top contact structure.

As shown in FIG. 11, the display device 50 is an active matrix display device that includes a pixel circuit and organic electroluminescent element EL in each pixel ‘a’ on the substrate 11. The pixel circuit uses a semiconductor device including a thin film transistor (hereinafter written as the thin film transistor 1). The organic electroluminescent element EL is connected to the pixel circuit.

The substrate 11 having the pixel circuits, each including the thin film transistor 1, arranged thereon is covered with a passivation film 51, and a planarizing insulating film 53 is provided on top of the passivation film 51. Both the passivation film 51 and planarizing insulating film 53 have connection holes 51a each of which reaches one of the thin film transistors 1. Pixel electrodes 55 are arranged and formed on top of the planarizing insulating film 53. The same electrodes 55 are each connected to one of the thin film transistors 1 via the connection hole 51a.

The periphery of each of the pixel electrodes 55 is covered with a window insulating film 57 for isolation. Each of the isolated pixel electrodes 55 is covered on top with one of organic light emitting functional layers 59r, 59g and 59b of different colors. Further, the organic light emitting functional layers 59r, 59g and 59b are covered with a common electrode 61 shared among the pixels ‘a.’ Each of the organic light emitting functional layers 59r, 59g and 59b has a layered structure including at least an organic light emitting layer. The organic light emitting layer differs in pattern from one pixel to another. The organic light emitting functional layers 59r, 59g and 59b may have a layer shared among the pixels. The common electrode 61 is formed, for example, as a cathode. Further, if the display device manufactured here is a top emission type in which emitted light is extracted from the side opposite to the substrate 11, the common electrode 61 is formed as a light transmitting electrode.

As described above, the organic electroluminescent element EL is formed at each of the pixels ‘a’ where one of the organic light emitting functional layers 59r, 59g and 59b is sandwiched between the pixel electrodes 55 and common electrode 61. It should be noted that although not shown, a protective layer is further provided above the substrate 11 on which the organic electroluminescent elements EL are formed, after which a sealing substrate is attached with an adhesive to manufacture the display device 50.

### <Circuit Configuration of the Display Device>

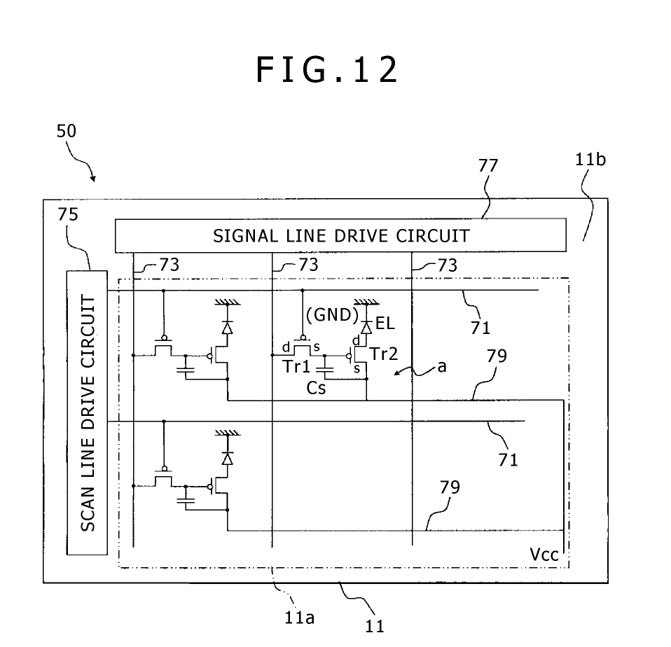

FIG. 12 illustrates an example of circuit configuration of the display device 50. It should be noted that the circuit configuration described here is merely an example.

As shown in FIG. 12, a display region 11a and surrounding region 11b are provided on the substrate 11 of the display device 50. A plurality of scan lines 71 are arranged horizontally and a plurality of signal lines 73 vertically in the display region 11a, with one of the pixels ‘a’ provided at each of the intersections between one of the scan lines 71 and one of the signal lines 73, thus making up a pixel array section. In the surrounding region 11b, on the other hand, a scan line drive circuit 75 and signal line drive circuit 77 are arranged. The scan line drive circuit 75 scans and drives the scan lines 71. The signal line drive circuit 77 supplies a video signal commensurate with luminance information (i.e., input signal) to the signal lines 73.

The pixel circuit provided at each of the intersections between one of the scan lines 71 and one of the signal lines 73 includes, for example, a switching thin film transistor Tr1, driving thin film transistor Tr2, holding capacitor Cs and organic electroluminescent element EL.

In the display device 50, a video signal written from the signal line 73 via the switching thin film transistor Tr1 as a result of the driving by the scan line drive circuit 75 is held by the holding capacitor Cs. As a result, a current commensurate with the held signal level is supplied from the driving thin film transistor Tr2 to the organic electroluminescent element EL, allowing for the same element EL to emit light at the luminance commensurate with the current. It should be noted that the driving thin film transistor Tr2 is connected to a common power supply line (Vcc) 79.

It should be noted that the pixel circuit configuration described above is merely an example. A capacitive element or a plurality of more transistors may be provided in the pixel circuit as necessary. On the other hand, necessary drive circuits are added to the surrounding region 11b to address the change in the pixel circuit.

In the circuit configuration described above, each of the thin film transistors Tr1 and Tr2 includes the thin film transistor (semiconductor device) according to the present disclosure illustrated by way of example in one of the embodiments. It should be noted that FIG. 11 shows a cross-sectional view of the area where the thin film transistor Tr2 and organic electroluminescent element EL are stacked as a cross-sectional view of three pixels of the display device 50 having the above circuit configuration. The switching thin film transistor Tr1 and capacitive element Cs are formed in the same layer as the driving thin film transistor Tr2. On the other hand, FIG. 12 illustrates a case in which the thin film transistors Tr1 and Tr2 are p-channel transistors.

In the display device 50 configured as described above, each of the pixel circuits includes the thin film transistors (semiconductor devices) with improved functionality as described in the first to fourth embodiments, thus providing higher packing density and higher functionality of the pixels.

It should be noted that an organic EL display device was illustrated by way of example in the fifth embodiment. However, the display device according to the present disclosure is widely applicable to display devices using thin film transistors, and particularly, to active matrix display devices having a thin film transistor connected to a pixel electrode, thus providing the same advantageous effect. Among examples of such display devices are liquid crystal display device and electrophoretic display device. The display device according to the present disclosure provides the same advantageous effect if used as any of the above display devices.

### 6. SIXTH EMBODIMENT

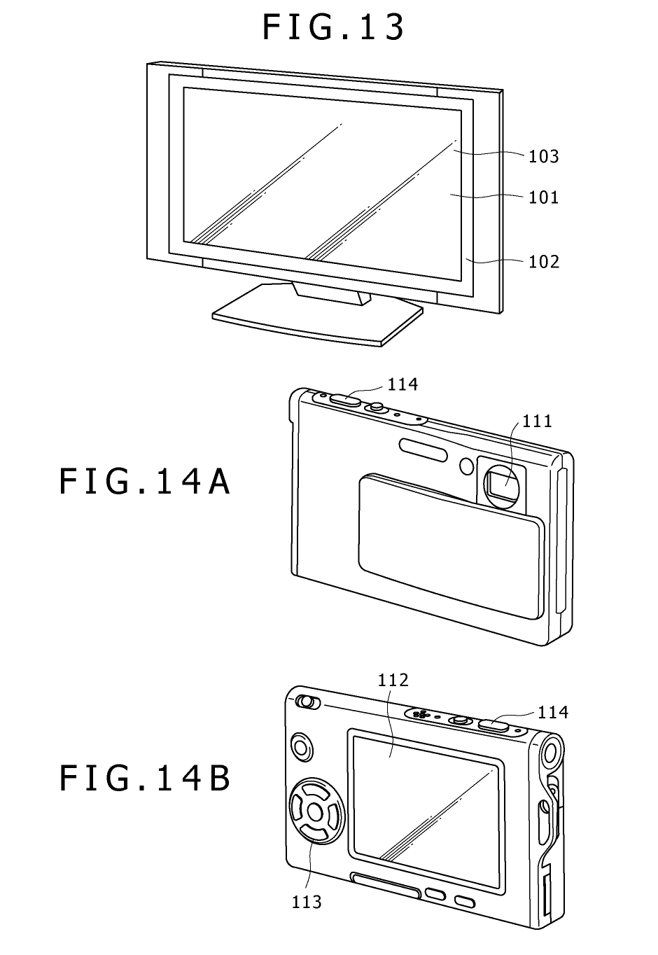

Examples of electronic equipment according to the present disclosure are described in FIGS. 13 to 17G. The pieces of electronic equipment described here use, for example, the display device described in the fifth embodiment as their display section. It should be noted that the display device according to the present disclosure, one of whose examples was described in the fifth embodiment, is applicable to the display section of electronic equipment across all disciplines adapted to display a video signal fed thereto or generated therein. Examples of such electronic equipment to which the present disclosure is applied will be described below.

FIG. 13 is a perspective view illustrating a television set to which the present disclosure is applied. The television set according to the present application example includes a video display screen section 101 made up of a front panel 102, filter glass 103 and other parts. The television set is manufactured by using the display device according to the present disclosure as the video display screen section 101.

FIGS. 14A and 14B are perspective views illustrating a digital camera to which the present disclosure is applied. FIG. 14A is a front view, and FIG. 14B a rear view. The digital camera according to the present application example includes a flash-emitting section 111, display section 112, menu switch 113, shutter button 114 and other parts. The digital camera is manufactured by using the display device according to the present disclosure as the display section 112.

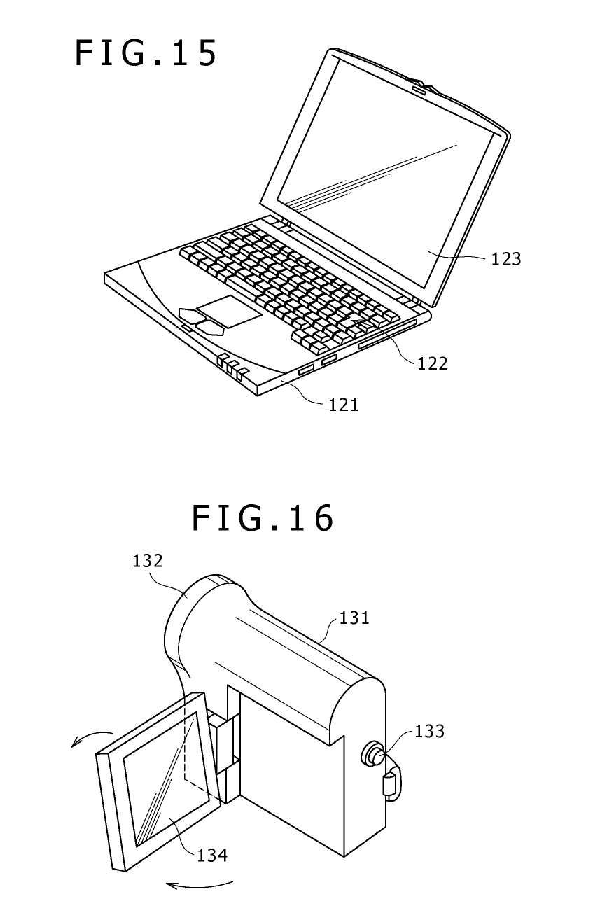

FIG. 15 is a perspective view illustrating a laptop personal computer to which the present disclosure is applied. The laptop personal computer according to the present application example includes a keyboard 122 adapted to be manipulated for entry of text or other information, a display section 123 adapted to display an image and other parts in a main body 121. The laptop personal computer is manufactured by using the display device according to the disclosure as the display section 123.

FIG. 16 is a perspective view illustrating a video camcorder to which the present disclosure is applied. The video camcorder according to the present application example includes a main body section 131, lens 132 provided on the front-facing side surface to capture the image of the subject, imaging start/stop switch 133, display section 134 and other parts. The video camcorder is manufactured by using the display device according to the present disclosure as the display section 134.

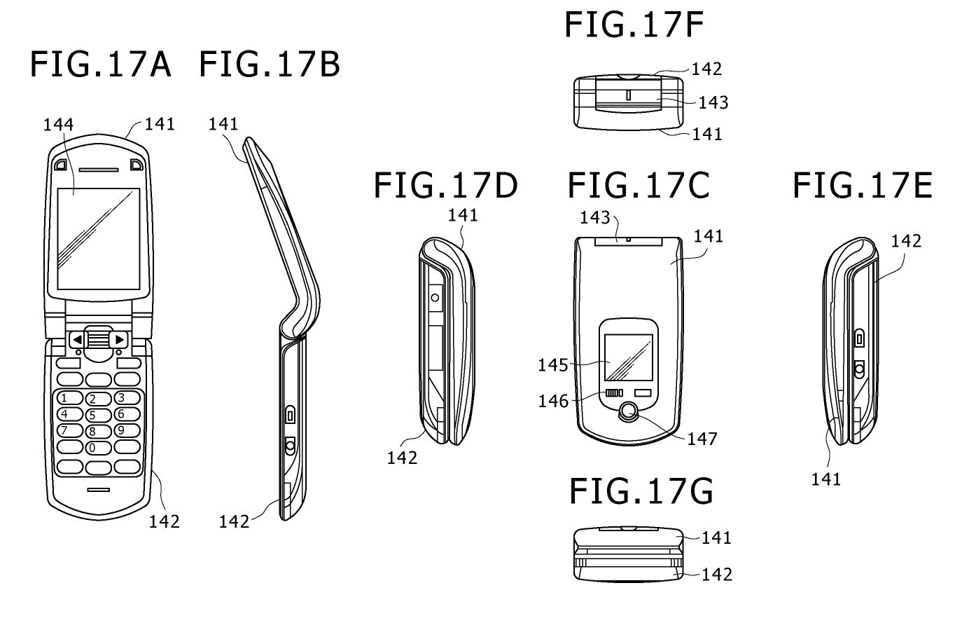

FIGS. 17A to 17G illustrate a personal digital assistance such as mobile phone to which the present disclosure is applied. FIG. 17A is a front view in an open position, FIG. 17B a side view thereof, FIG. 17C a front view in a closed position, FIG. 17D a left side view, FIG. 17E a right side view, FIG. 17F a top view, and FIG. 17G a bottom view. The mobile phone according to the present application example includes an upper enclosure 141, lower enclosure 142, connecting section (hinge section in this example) 143, display 144, subdisplay 145, picture light 146, camera 147 and other parts. The mobile phone according to the present application example is manufactured by using the display device according to the present disclosure as the display 144 and subdisplay 145.

It should be noted that electronic equipment having a display section was illustrated as examples of the electronic equipment according to the present disclosure in the sixth embodiment. However, the electronic equipment according to the present disclosure is applicable not only to those pieces of electronic equipment having a display section but also others incorporating a thin film transistor connected to a conductive pattern. Among examples of such electronic equipment are IC tags and sensors, and the electronic equipment according to the present disclosure provides the same advantageous effect if applied to these pieces of electronic equipment.

The present disclosure contains subject matter related to that disclosed in Japanese Priority Patent Application JP 2010-177798 filed in the Japan Patent Office on Aug. 6, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a gate electrode on a substrate;
a gate insulating film adapted to cover the gate electrode;
an organic semiconductor layer stacked above the gate electrode with the gate insulating film therebetween in such a manner as to cover the gate electrode along the width of the gate electrode, the organic semiconductor layer having a thick film portion and thin film portions, the thick film portion being arranged at the center along the width of the gate electrode, the thin film portions being thinner than the thick film portion and arranged each at one end along the width of the gate electrode; and
source and drain electrodes arranged to be opposed to each other with the gate electrode sandwiched therebetween along the width of the gate electrode, with the end portion of each of the source and drain electrodes stacked on one of the thin film portions of the organic semiconductor layer.

2. The semiconductor device of claim 1, wherein
the thick film portion of the organic semiconductor layer fits within the width of the gate electrode, and
the thin film portions extend outward from the thick film portion along the width of the gate electrode.

3. The semiconductor device of claim 1, wherein
the organic semiconductor layer comprises:
a first layer provided to fit within the width of the gate electrode; and
a second layer provided to cover the first layer.

4. The semiconductor device of claim 1, wherein
the source and drain electrodes are stacked in such a manner as to reach the thick film portion of the organic semiconductor layer.

5. The semiconductor device of claim 1, wherein
the end portions of the source and drain electrodes are aligned with the edges along the width of the gate electrode when seen in a plan view.

6. The semiconductor device of claim 1, wherein
the thick film portion of the organic semiconductor layer has its top surface covered with an insulating protective film.

7. A display device comprising:
a thin film transistor; and
a pixel electrode connected to the thin film transistor, the thin film transistor including
a gate electrode on a substrate,
a gate insulating film adapted to cover the gate electrode,
an organic semiconductor layer stacked above the gate electrode with the gate insulating film therebetween in such a manner as to cover the gate electrode along the width of the gate electrode, the organic semiconductor layer having a thick film portion and thin film portions, the thick film portion being arranged at the center along the width of the gate electrode, the thin film portions being thinner than the thick film portion and arranged each at one end along the width of the gate electrode, and
source and drain electrodes arranged to be opposed to each other with the gate electrode sandwiched therebetween along the width of the gate electrode, with the end portion of each of the source and drain electrodes stacked on one of the thin film portions of the organic semiconductor layer.

8. The display device of claim 7, wherein
the thick film portion of the organic semiconductor layer fits within the width of the gate electrode, and
the thin film portions extend outward from the thick film portion along the width of the gate electrode.

9. Electronic equipment comprising:
a thin film transistor, the thin film transistor including
a gate electrode on a substrate,
a gate insulating film adapted to cover the gate electrode,
an organic semiconductor layer stacked above the gate electrode with the gate insulating film therebetween in such a manner as to cover the gate electrode along the width of the gate electrode, the organic semiconductor layer having a thick film portion and thin film portions, the thick film portion being arranged at the center along the width of the gate electrode, the thin film portions being thinner than the thick film portion and arranged each at one end along the width of the gate electrode, and
source and drain electrodes arranged to be opposed to each other with the gate electrode sandwiched therebetween along the width of the gate electrode, with the end portion of each of the source and drain electrodes stacked on one of the thin film portions of the organic semiconductor layer.

10. The electronic equipment of claim 9, wherein
the thick film portion of the organic semiconductor layer fits within the width of the gate electrode, and
the thin film portions extend outward from the thick film portion along the width of the gate electrode.
